(19) United States
(12) Patent Application Publication
(10) Pub. No.: US 2015/0207019 A1
(43) Pub. Date: Jul. 23, 2015

(54) Method for Fabricating Crystalline Silicon Solar Cell Having Passivation Layer and Local Rear Contacts

(71) Applicant: National Tsing Hua University, Hsinchu City (TW)

(72) Inventors: Li-Karn Wang, Hsinchu City (TW); Chung-Kai Liang, Hsinchu City (TW)

(21) Appl. No.: 14/488,473

(22) Filed: Sep. 17, 2014

(30) Foreign Application Priority Data
Jan. 17, 2014 (TW) 103101898

(51) Int. Cl. H01L 31/18; H01L 31/0224; H01L 31/028; H01L 31/0216; H01L 31/056; H01L 31/0745

(52) U.S. Cl. CPC H01L 31/1804; H01L 31/056; H01L 31/0745; H01L 31/028; H01L 31/02168; H01L 31/022441

(57) ABSTRACT

The present invention is a method for fabricating a crystalline silicon solar cell having a passivation layer and a plurality of local rear contacts, which comprises steps of forming a passivation layer on the rear surface of the silicon substrate; coating distributed metal electrodes on the rear surface and forming a plurality of local rear contacts through firing and forming a metallic reflector at the rear surface so that the metallic reflector electrically contacts with the plurality of local rear contacts.

### FIELD OF THE INVENTION

The present invention relates to a method for fabricating a crystalline solar cell, where a silicon substrate has a passivation layer and a plurality of local rear contacts on its rear surface, thereby the fabricating steps are reduced in number.

### DESCRIPTION OF THE RELATED ART

For the currently available crystalline silicon solar cells, a P-type solar grade silicon substrate is used. Then, a light exposure face is formed, i.e. a front surface is texturized, and then a phosphorus diffusion process is carried out to form a P-N junction. Subsequently, an antireflection coating, a contact formation, a firing, and an edge isolation processes are applied.

To promote the photoelectric conversion efficiency of the solar cell, there has been a structure having a passivation layer deposited and meanwhile local rear contacts formed on the rear surface of the silicon substrate used. The passivation layer is usually made of a dielectric material, such as silicon dioxide, silicon nitride, or aluminum oxide. Among them, the aluminum oxide Al₂O₃ thin film can be the best in effect, which is usually deposited on the rear surface of the silicon substrate by using an atomic layer deposition method.

To promote the reflectivity of the rear surface and protect the passivation layer, a dielectric insulating layer is deposited on the passivation layer. A commonly used dielectric insulating layer may be silicon dioxide or silicon nitride, and generally formed by a PECVD (plasma enhanced chemical vapor deposition) method. To form the local rear contacts on the silicon substrate, a photolithographic method may be used, or an anti-etching paste is printed on the dielectric insulating layer by using a screen printing or inkjet method to define opened regions. Thereafter, distributed openings are formed by immersing the substrate in aqueous acid-etching solution. The openings can also be formed by laser ablation. In this way, the back electrodes usually made of aluminum may get contact with the silicon substrate through the openings. After fired, local rear contacts with local back surface fields (local BSFs) are formed. In addition, there may also be a choice that the coated metal electrode material is fired by laser, together with the two dielectric layers (including the passivation layer and the dielectric insulation layer) and a part of the silicon substrate to form laser fired contacts.

A prior structure for the local rear contact P-type silicon solar cell is exemplified in FIG. 1, where the surface of a P-type silicon substrate 10 is texturized. A phosphorus diffusion process is performed to form an N-type silicon semiconductor layer 11 on the front surface of the silicon substrate, i.e. the light exposure face. Next, the anti-reflection layer 12 is formed on the N-type silicon semiconductor layer 11. Then, a dielectric passivation layer 13 is deposited on the rear surface of the silicon substrate.

If the adopted dielectric passivation layer is Al₂O₃, then it induces a negative charge layer at the silicon/Al₂O₃ interface making the rear surface passivated, and the back surface recombination velocity reduced, and henceforth increasing the open circuit voltage V_{OC}. The dielectric insulating layer 14 deposited on the dielectric passivation layer 13 is taken as a protection layer preventing the dielectric passivation layer 13 from being damaged by the metallic material when the metal electrodes on the rear surface is fired, and also taken as a material for promoting the reflectivity of the rear surface. The promotion of the rear surface reflectivity benefits generation of more electron-hole pairs induced by increasing long-wavelength photons, which increases a short circuit current density J_{SC}, and henceforth promoting the photoelectric conversion efficiency. The dielectric insulating layer 14 may be a layer of silicon oxide or silicon nitride.

In the aforementioned method, a silver paste and an aluminum paste are coated on the front and the rear surfaces, respectively. The aluminum paste is coated on the whole rear surface after the distributed open regions of the dielectric passivation layer and the dielectric insulating layer are formed on the rear surface, and a back surface field (BSF) region 16 is formed through a co-firing process. The silver paste can be coated by either a photolithographic process, a printing method or an inkjet method on the front surface, and the aluminum paste can be coated on the whole rear surface by the same method mentioned herein. After a co-firing process, the front surface electrodes 15 and the rear surface electrode 17 are formed.

The rear surface electrode 17 and the silicon substrate 10 form local rear contacts. Conventionally, the rear surface of the silicon substrate 10 is also printed with an electrode material containing silver to serve as soldering pads for connecting a plurality of crystalline silicon solar cells to form a solar panel.

It may be known from the above that an additional process is required to form the distributed openings after the dielectric passivation layer and the dielectric insulating layer are formed in the conventional manufacturing process for the crystalline silicon solar cells having a high rear surface reflectivity and local rear contacts, and the whole rear surface has to be coated with the metal electrode material. In the case of the Al₂O₃ layer for passivation, an ALD (atomic layer deposition) machine may be used. The dielectric insulating layer is typically a silicon oxide or silicon nitride thin film coated by using a PECVD machine. Such a thin film deposition equipment does not refer to a low-cost process, counting in the costs of the equipment, maintenance, personnel expense and expendables. For this reason, the present invention discloses a novel method for fabricating a structure having the local rear contacts on the rear surface, to save the manufacturing cost.

### SUMMARY OF THE INVENTION

The present invention discloses a method for fabricating a crystalline silicon solar cell having a passivation layer and a plurality of local rear contacts.

In accordance with a first embodiment, the method of the present invention comprises at least steps of providing a silicon substrate, being one of a single-crystal silicon and a polysilicon, having one of a P-type doping and an N-type doping, and having a front surface and a rear surface opposed thereto, wherein the front surface has at least a semiconductor layer that has a doping opposite to the doping of the silicon substrate; forming a passivation layer on the rear surface of the silicon substrate; coating distributed metal electrodes on the rear surface of the silicon substrate; coating metal electrodes on the front surface of the silicon substrate; co-firing the front metal electrodes and the rear metal electrodes to form, respectively, front contacts on the front surface and a plurality of local rear contacts on the rear surface, wherein a portion of the silicon substrate adjacent to the local rear contacts on the rear surface is a back surface field region; and forming a metallic reflector above the rear surface of the silicon substrate, so that the metallic reflector electrically contacts with the plurality of local rear contacts.

In accordance with a second embodiment of the present invention, the method comprises at least steps of: providing a silicon substrate, being one of a single crystal silicon and a polysilicon, having one of a P-type doping and an N-type doping, and having a front surface and a rear surface opposed thereto, wherein the front surface has a first semiconductor layer and a second semiconductor layer both having a doping opposite to the doping of the silicon substrate, and the doping concentration of the first semiconductor layer is larger than the doping concentration of the second semiconductor layer; forming a passivation layer on the rear surface of the silicon substrate; coating distributed metal electrodes on the rear surface of the silicon substrate; coating metal electrodes on the front surface at the regions above the first semiconductor layer; co-firing the front and rear metal electrodes to form, respectively, the front contact and a plurality of local rear contacts, wherein a portion of the silicon substrate adjacent to the local rear contacts on the rear surface is a back surface field region; forming a metallic reflector above the rear surface of the silicon substrate, so that the metallic reflector electrically contacts with the plurality of local rear contacts.

The present invention discloses a technology for forming a passivation layer and local rear contacts on the rear surface of a crystalline silicon solar cell, which may be applied to single-crystalline and polycrystalline solar cells. It aims at effectively reducing the fabrication cost while maintaining a high photoelectric conversion efficiency of the crystalline silicon solar cell having a plurality of local rear contacts. In an example according to the present invention, some of the fabrication processes of the prior arts are first performed on a light exposure surface, comprising texturization, electricity doping for forming a P-N junction, and an antireflection layer coating. On the front surface, there may also be a passivation layer to further promote performance of the solar cell. Further, a structure having a selective emitter may also be formed on the front surface to promote the performance of the solar cell. In addition, the front surface may also be formed with a heterojunction structure, i.e. a single or a plurality of thin films with an electronic bandgap different from that of silicon substrate is formed on the front surface of the silicon substrate having the electricity doping, and thus an internally built electric field is produced.

In the present invention, a metallic reflector is used at the rear side of the silicon substrate for, on one hand, reflecting unabsorbed light back into the silicon substrate and, on the other hand, to collect photogenerated current from the plurality of local rear contacts. In some cases where thick enough silicon substrates are used, the metallic reflector may not function as a light reflector, but is solely used to collect the electric current.

The fabricating method of the present invention has the following advantages: (1) the high photoelectric conversion efficiency of the conventional solar cell having the local rear contacts is maintained, (2) the fabrication steps are effectively reduced, (3) the performance of the solar cell is promoted, (4) the machine equipments for formation of the dielectric insulation layer and the formation of the openings at the rear side of the silicon substrate, as well as the expenditure for maintenance and personnel are saved, and (5) the use of the electrode material is reduced to a great extent.

### BRIEF DESCRIPTIONS OF THE DRAWINGS

The present invention will be better understood from the following detailed descriptions of the preferred embodiments according to the present invention, taken in conjunction with the accompanying drawings, in which:

FIG. 1 is a cross sectional diagram of a solar cell having local rear contacts used in the prior art;

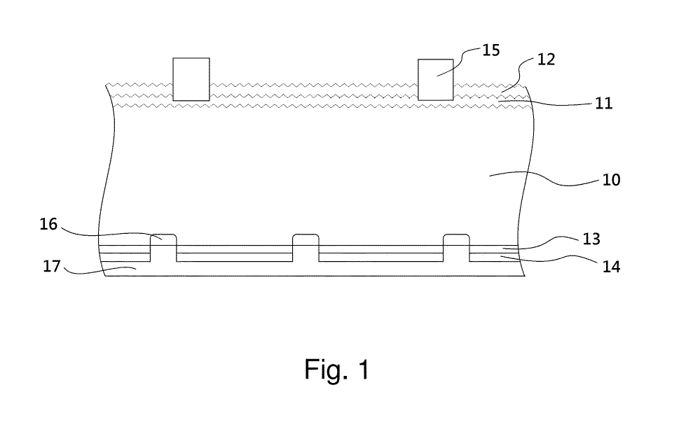

FIG. 2 is a cross sectional diagram of a solar cell having local rear contacts according to the present invention;

FIG. 3 is a flowchart of a method for fabricating the solar cell having a passivation layer and local rear contacts according to a first embodiment of the present invention; and

FIG. 4 is a flowchart of a method for fabricating the solar cell having a passivation layer and local rear contacts according to a second embodiment of the present invention.

### DESCRIPTION OF THE PREFERRED EMBODIMENTS

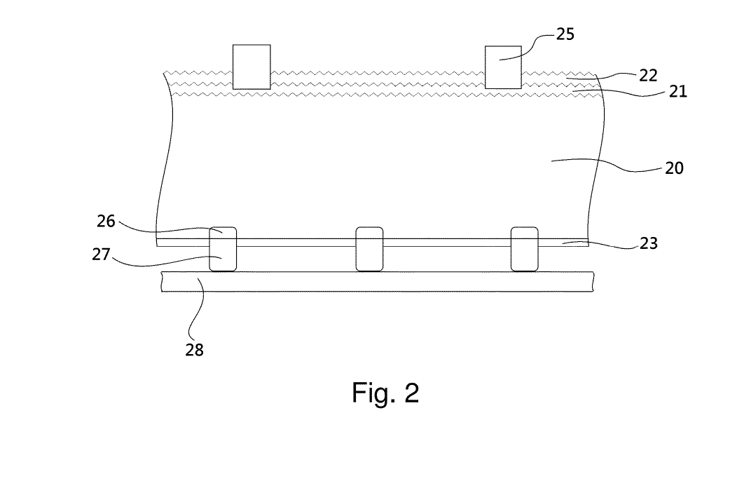

The present invention is a fabricating method for a crystalline silicon solar cell having a passivation layer and a plurality of local rear contacts. The silicon substrate may be a P-type or N-type silicon substrate, and has a thickness between from 2 μm to 750 μm. However, the present invention is described by taking the P-type silicon substrate as an example. A preferred embodiment of such solar cell is shown in FIG. 2. In the preferred embodiment, the P-type substrate 20 after texturization has an N-type semiconductor layer 21 formed on its front surface through a phosphorus diffusion process. Next, an anti-reflection layer 22 is formed on the texturized front surface; a dielectric passivation layer 23 is formed on the silicon substrate 20 at its rear surface by using atomic layer vapor deposition, PECVD, sputtering, evaporation, or thermal oxidation process. The thickness of the dielectric passivation layer 23 is not larger than 200 nm.

In another preferred embodiment, the anti-reflection layer 22 is formed after the dielectric passivation layer 23. Thereafter, a screen printing or an inkjet method is used to coat a metallic material on the front and rear surfaces, to form the front surface electrodes 25 and the local rear contacts 27. The local rear contacts 27 at the rear surface may take a shape of a plurality of dots or a plurality of stripes.

The front surface electrode 25 contains at least one of silver (Ag), aluminum (Al), titanium (Ti), palladium (Pd), copper (Cu), and nickel (Ni), while the local rear contacts 27 may adopt a material containing Al. After a firing process, the front surface metal melts through the anti-reflection layer to contact with the N-type semiconductor, while the rear surface metal melts through the dielectric passivation layer to produce a back surface field (BSF) 26 in the silicon substrate.

In another preferred embodiment, the dielectric passivation layer may be patterned first to form openings, and then an metal electrode material is coated on the openings. A plurality of local rear contacts are then formed through firing. Thereafter, a metallic reflector 28 is used, which has a region size larger than or equal approximately to the region of the P-type silicon substrate 20. By applying a conductive glue locally or wholly on the rear surface of the P-type silicon substrate 20, the metallic reflector 28 is contacted with and thus fixed onto the local rear contacts 27.

In another preferred embodiment, the metallic reflector 28 is made contacted with the local rear contacts 27 by attaching the metallic reflector 28 upon the P-type silicon substrate 20 with non-conductive glue applied at a part of regions of the P-type silicon substrate 20.

In another preferred embodiment, the metallic reflector 28 is made contacted with the local rear contacts 27 before firing (usually co-firing). After firing, there forms metal bonding between the metallic reflector 28 and the local rear contacts 27. In another preferred embodiment, the metallic reflector 28 and the local rear contacts 27 are made fixed and contacted with each other by using an external package. In another preferred embodiment, the metallic reflector 28 is formed of a smooth metallic sheet containing at least one of Al, Cu and Ni. In another preferred embodiment, a thin film containing at least one of Al, Cu and Ni is coated on a thin non-metallic plate to form the metallic reflector 28. In another preferred embodiment, after the local rear contacts 27 and the BSFs 26 are formed, a metal thin film is coated by evaporation, electroplating or sputtering directly on the rear surface of P-type silicon substrate 20.

In another preferred embodiment, the P-type silicon substrate 20 has a selective emitter structure at its front surface. That is, the front surface has a first semiconductor layer and a second semiconductor layer, and the first and the second semiconductor layers both have a doping opposite to that of the silicon substrate. The doping concentration of the first semiconductor layer is larger than that of the second semiconductor layer. The electrodes on the front surface of the silicon substrate are coated at a region above the first semiconductor layer. In another embodiment, the silicon substrate has a heterojunction structure at its front surface, i.e. one or a plurality of thin films with an electronic bandgap different from that of the silicon substrate is formed on the front surface of the silicon substrate having the electricity doping, and thus an internally built electric field is produced.

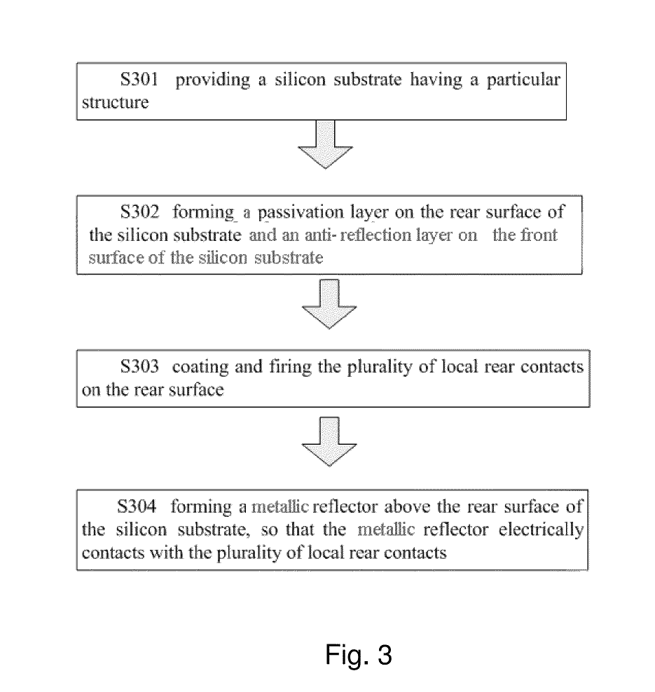

In conclusion, the method of the present invention comprises at least the following steps. At first, a silicon substrate having a particular structure, is provided (S301 in FIG. 3), which is a single crystal silicon or a polysilicon, having a P-type doping or an N-type doping, and having a front surface and a rear surface opposed thereto. Further, the front surface has at least a semiconductor layer having a doping opposite to the doping of the silicon substrate. Thereafter, a passivation layer is formed on the rear surface of the silicon substrate and an anti-reflection layer is formed on the front surface of the silicon substrate (S302). Thereafter, metal electrodes are coated on the front surface and the rear surface and fired to form the front contacts and a plurality of local rear contacts (S303). Then, a metallic reflector above the rear surface of the silicon substrate is formed, so that the metallic reflector electrically contacts with the plurality of local rear contacts (S304).

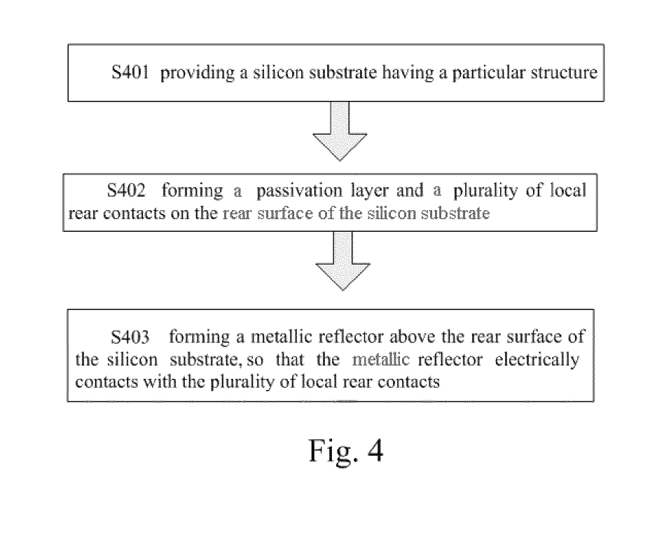

In accordance with a second embodiment of the present invention, the method comprises at least the following steps. At first, a silicon substrate having a particular structure is provided (S401 in FIG. 4), which is a single crystal silicon or a polysilicon, having one of a P-type doping and an N-type doping, and having a front surface and a rear surface opposed thereto. Further, the front surface has a first semiconductor layer and a second semiconductor layer both having a doping opposite to that of the silicon substrate, and the doping concentration of the first semiconductor layer is larger than the doping concentration of the second semiconductor layer. A passivation layer and a plurality of local rear contacts on the rear surface of the silicon substrate are formed (S402). Then, a metallic reflector above the rear surface of the silicon substrate is formed (S403), so that the metal reflector electrically contacts with the plurality of local rear contacts, wherein a portion of the silicon substrate adjacent to the plurality of local rear contacts on the rear surface is a BSF region.

The above described is merely examples and preferred embodiments of the present invention, and not exemplified to intend to limit the present invention. Any modifications and changes without departing from the scope of the spirit of the present invention are deemed as within the scope of the present invention. The scope of the present invention is to be interpreted with the scope as defined in the claims.

1. A method for fabricating a crystalline silicon solar cell having a single passivation layer on its rear side and a plurality of local rear contacts, comprising at least the steps of:
providing a silicon substrate, being one of single crystal silicon and polysilicon, having one of P-type doping and N-type doping, and having a front surface and a rear surface opposed thereto;
forming an anti-reflection layer on said front surface of said silicon substrate;
forming a single passivation layer on said rear surface of said silicon substrate;
forming a plurality of local rear contacts on said rear surface of said silicon substrate;
forming, on said front surface, at least a semiconductor layer having a doping opposite to the doping of said silicon substrate and having an electronic bandgap different from that of said silicon substrate;
forming electrodes on said front surface of said substrate; and
forming a metallic reflector above said rear surface of said silicon substrate, so that said metallic reflector electrically contacts with said plurality of local rear contacts, wherein a portion of said silicon substrate adjacent to said plurality of local rear contacts on said rear surface is a back surface field region.

2. A method for fabricating a crystalline silicon solar cell having a single passivation layer on its rear side and a plurality of local rear contacts comprising at least the steps of:
providing a silicon substrate, being one of a single crystal silicon and a polysilicon, having one of P-type doping and N-type doping, and having a front surface and a rear surface opposed thereto, wherein said front surface has a selective emitter structure of a first semiconductor layer and a second semiconductor layer both having a doping opposite to the doping of said silicon substrate, and the doping concentration of said first semiconductor layer is larger than the doping concentration of said second semiconductor layer;
forming an anti-reflection layer on said front surface of said silicon substrate;
forming a single passivation layer and a plurality of local rear contacts on said rear surface of said silicon substrate;
forming electrodes at the regions of said first semiconductor layer on said front surface of said silicon substrate; and
forming a metallic reflector above said rear surface of said silicon substrate, so that said metallic reflector electrically contacts with said plurality of local rear contacts, wherein a portion of said silicon substrate adjacent to said plurality of local rear contacts on said rear surface is a back surface field region.

3. The method as claimed in claim 1, wherein at least one of said front and rear surfaces is a texturized surface, which contains a pyramid or other irregular topology structure.

4. The method as claimed in claim 2, wherein at least one of said front and rear surfaces is a texturized surface, which contains a pyramid or other irregular topology structure.

5. (canceled)

6. The method as claimed in claim 1, wherein said passivation layer on said rear surface contains one of aluminum oxide, silicon oxide, hydrogenated amorphous silicon, aluminum fluoride, and aluminum nitrate.

7. The method as claimed in claim 2, wherein said passivation layer on said rear surface contains one of aluminum oxide, silicon oxide, hydrogenated amorphous silicon, aluminum fluoride, and aluminum nitrate.

8. The method as claimed in claim 1, wherein said metallic reflector at least contains one of aluminum, copper, nickel, silver, platinum and rhodium and has a reflectivity between 20% and 100%.

9. The method as claimed in claim 2, wherein said metallic reflector at least contains one of aluminum, copper, nickel, silver, platinum and rhodium and has a reflectivity between 20% and 100%.

10. The method as claimed in claim 1, wherein said metallic reflector is formed of a non-metal plate coated with a thin metallic film at least containing one of aluminum, copper, nickel, silver, platinum, and rhodium, wherein said metallic film has a thickness between 10 nm and 100 μm, and said non-metal plate has a thickness between 5 μm and 20 mm.

11. The method as claimed in claim 1, wherein said metallic reflector is formed by evaporating, electroplating, or sputtering a thin metallic conductive film on said rear surface of said silicon substrate.

12. The method as claimed in claim 2, wherein said metallic reflector is formed by evaporating, electroplating, or sputtering a thin metallic conductive film on said rear surface of said silicon substrate.

13. The method as claimed in claim 1, wherein the electrical contact between said metallic reflector and said plurality of local rear contacts on said rear surface is formed by a method selected from a group of:
(1) applying a transparent conductive glue onto a portion of said rear surface of said silicon substrate, so that said metallic reflector is fixed onto and contacted with said plurality of local rear contacts;
(2) applying a non-conductive glue onto a portion of said rear surface of said silicon substrate, so that said metallic reflector is fixed onto and contacted with said plurality of local rear contacts;
(3) bringing said metallic reflector to contact with said plurality of local rear contacts, and firing said metallic reflector together with said plurality of local rear contacts to be connected together; and
(4) bringing said metallic reflector to contact with said plurality of local rear contacts, and packaging said metallic reflector together with said plurality of local rear contacts by a frame.

14. The method as claimed in claim 2, wherein the electrical contact between said metallic reflector and said plurality of local rear contacts on said rear surface is formed by a method selected from a group of:
(1) applying a transparent conductive glue onto a portion of said rear surface of said silicon substrate, so that said metallic reflector is fixed onto and contacted with said plurality of local rear contacts;
(2) applying a non-conductive glue onto a portion of said rear surface of said silicon substrate, so that said metallic reflector is fixed onto and contacted with said plurality of local rear contacts;
(3) bringing said metallic reflector to contact with said plurality of local rear contacts, and firing said metallic reflector together with said plurality of local rear contacts to be connected together; and
(4) bringing said metallic reflector to contact with said plurality of local rear contacts, and packaging said metallic reflector together with said plurality of local rear contacts by a frame.
